(19) United States
(12) Patent Application Publication
(10) Pub. No.: US 2024/0332438 A1
(43) Pub. Date: Oct. 3, 2024

(54) WAVEGUIDE-TYPE LIGHT-RECEIVING ELEMENT, WAVEGUIDE-TYPE LIGHT-RECEIVING ELEMENT ARRAY, AND METHOD FOR MANUFACTURING WAVEGUIDE-TYPE LIGHT-RECEIVING ELEMENT

(71) Applicant: Mitsubishi Electric Corporation, Tokyo (JP)

(72) Inventor: Ryota TAKEMURA, Tokyo (JP)

(73) Assignee: Mitsubishi Electric Corporation, Tokyo (JP)

(21) Appl. No.: 18/576,494

(22) PCT Filed: Oct. 14, 2021
(86) PCT No.: PCT/JP2021/038000

§ 371 Date: Jan. 4, 2024

(51) Int. Cl. H01L 31/0232; H01L 31/0304; H01L 31/18

(52) U.S. Cl. CPC H01L 31/02327; H01L 31/1844; H01L 31/03046

(57) ABSTRACT

A waveguide-type light-receiving element of the present disclosure includes: a semiconductor substrate; a ridge waveguide including a first-conductivity-type contact layer, a first-conductivity-type cladding layer, a light absorption layer, and a second-conductivity-type cladding layer, which are laminated above the semiconductor substrate, the ridge waveguide having a light incident surface separated from one end of the semiconductor substrate and a rear surface separated from the other end of the semiconductor substrate; a first semiconductor buried region provided in contact with the light incident surface and having a light incident end surface that is one surface on a light incident side and is separated from the one end of the semiconductor substrate; and a second semiconductor buried region provided in contact with the rear surface and having a rear end surface that is one surface facing the rear surface and is separated from the other end of the semiconductor substrate.

### TECHNICAL FIELD

The present disclosure relates to a waveguide-type light-receiving element, a waveguide-type light-receiving element array, and a method for manufacturing a waveguide-type light-receiving element.

### BACKGROUND ART

With a dramatic increase in communication capacity, communication systems have been increasing in capacity. To increase the capacity of communication systems, it is essential to increase the speed of optical communication apparatus. A CR time constant is one of factors that determine a response speed of a photodiode (hereinafter referred to as a PD) which is a semiconductor light-receiving element used for the optical communication apparatus. The CR time constant is determined by element capacitance and element resistance of the semiconductor light-receiving element. To increase the response speed of the PD, it is necessary to make the CR time constant as small as possible. Therefore, it is important to reduce the element capacitance of the PD.

For example, in order to realize a high-speed response equal to or higher than 40 GHZ, a waveguide-type light-receiving element capable of reducing the element capacitance is used as an element structure of the PD. The waveguide-type light-receiving element has the element structure in which light is made incident from a side surface of epitaxial crystal growth layers, and unlike a normal surface incident type structure, photosensitivity and light-receiving band can be individually optimized. Consequently, it can be said that the waveguide-type light-receiving element has the element structure suitable for high-speed operation.

The waveguide-type light-receiving element is further roughly classified into two types. One of them is a loaded-type light-receiving element disclosed in Patent Document 1, for example. In the loaded-type light-receiving element, an optical waveguide is formed up to cleaved end surfaces. Light is made incident on the optical waveguide, light is guided to a light absorption layer formed at a position several μm or more away from the incident portion, and evanescent light leaking from the guide layer in the layer thickness direction is photoelectrically converted in the light absorption layer. Consequently, photoelectric conversion is indirect in the loaded-type light-receiving element, and thus concentration of photocurrent in the vicinity of the incident end surface is relaxed, as a result, there is an advantage that deterioration of the response speed hardly occurs even when light with high intensity is incident. On the other hand, there is also a disadvantage that it is difficult in principle to obtain high photosensitivity because light leaking out from the guide layer in the layer thickness direction is photoelectrically converted.

As a light-receiving element for solving the above problem, an element structure in which light is directly incident on the light absorption layer (Patent Document 2) or an element structure in which the light absorption layer and the like are buried by a semiconductor buried layer (Patent Document 3) is known. In these element structures, since light is directly incident on the light absorption layer through the window layer, high photosensitivity can be obtained without increasing the optical waveguide length so much. Consequently, in the above-described element structures, the element capacitance can also be reduced, and thus it is easy to achieve both high photosensitivity and high-speed response.

In an element structure in which light is directly incident on the light absorption layer, a junction portion is covered with an insulating film. In such element structures, since the insulating film has poor heat dissipation, the heat dissipation is worse than that of an element structure in which the light absorption layer is buried in a semiconductor material. As a result, particularly when a light input is increased, the element characteristics are deteriorated or the light-receiving element itself is deteriorated. From the above, it can be said that the element structure in which the light absorption layer is buried by the semiconductor buried layer is a desirable element structure in terms of element characteristics and reliability.

### CITATION LIST

### Patent Document

Patent Document 1: Japanese Patent No. 3757955
Patent Document 2: Japanese Patent Application Laid-Open No. 2001-223369
Patent Document 3: Japanese Patent No. 5294558

### SUMMARY OF THE INVENTION

### Problems to be Solved by the Invention

According to Patent Document 3, conventionally, in a waveguide-type light-receiving element having the element structure in which the light absorption layer and the like are buried by the semiconductor buried layer, a light incident end surface of a chip is formed by cleavage or other means after completion of a wafer process. When the cleavage position varies, a distance from the incident end surface to the light absorption layer (hereinafter referred to as window length) varies. Consequently, when the cleavage position is shifted in a direction away from the light absorption layer, the window length is formed longer. In addition, in order to cover the light absorption layer with the semiconductor buried layer even if the cleavage position varies, it is necessary to set the window length to be longer than the amount of variation in cleavage, resulting in an overall longer window length.

When the window length is long in the light-receiving element, light incident on the incident end surface leaks out from the upper portion of the semiconductor buried layer before reaching the light absorption layer, and thus the amount of light incident on the light absorption layer decreases, resulting in a decrease in photosensitivity. In addition, in a case where a region formed of a semiconductor material having a composition that absorbs light is present at the bottom of the semiconductor buried layer, absorption of light by such region increases when the window length is long, resulting in a decrease in the amount of light incident on the light absorption layer and thus a decrease in photosensitivity.

That is, conventional waveguide-type light-receiving element with the element structure in which the light absorption layer and the like are buried by the semiconductor buried layer, have a problem in the element structure in that the window length becomes longer, resulting in a decrease in photosensitivity.

The present disclosure has been made to solve the above-described problems, and an object of the present disclosure is to provide a waveguide-type light-receiving element and a waveguide-type light-receiving element array, which are capable of controlling the window length to be short and obtaining high photosensitivity, and a method for manufacturing the waveguide-type light-receiving element.

### Means to Solve the Problem

A waveguide-type light-receiving element according to the present disclosure includes: a semiconductor substrate; a ridge waveguide including at least a first-conductivity-type contact layer, a first-conductivity-type cladding layer, a light absorption layer, a second-conductivity-type cladding layer, and a second-conductivity-type contact layer, which are laminated above the semiconductor substrate, the ridge waveguide having a light incident surface separated from one end of the semiconductor substrate and a rear surface separated from the other end of the semiconductor substrate; a first semiconductor buried region provided in contact with the light incident surface of the ridge waveguide and having a light incident end surface that is one surface on a light incident side and is separated from the one end of the semiconductor substrate; and a second semiconductor buried region provided in contact with the rear surface of the ridge waveguide and having a rear end surface that is one surface facing the rear surface and is separated from the other end of the semiconductor substrate.

A waveguide-type light-receiving element array according to the present disclosure includes: a plurality of the above-mentioned waveguide-type light-receiving elements integrated in parallel such that the ridge waveguides of the waveguide-type light-receiving elements are located parallel to each other.

A method for manufacturing the waveguide-type light-receiving element according to the present disclosure includes: laminating sequentially at least a first-conductivity-type contact layer, a first-conductivity-type cladding layer, a light absorption layer, a second-conductivity-type cladding layer, and a second-conductivity-type contact layer above a semiconductor substrate by crystal growth; forming a ridge waveguide having a light incident surface on a light incident side and a rear surface on a side opposite to the light incident side by etching the light absorption layer, the second-conductivity-type cladding layer, the second-conductivity-type contact layer, and at least a part of the first-conductivity-type cladding layer; crystal-growing a semiconductor buried layer so as to bury the ridge waveguide; and forming, by etching the semiconductor buried layer, a first semiconductor buried region having a light incident end surface on a light incident surface side of the ridge waveguide, the light incident end surface being separated from one end of the semiconductor substrate, and a second semiconductor buried region having a rear end surface on a rear surface side of the ridge waveguide, the rear end surface being separated from the other end of the semiconductor substrate and facing the rear surface.

### Effect of the Invention

According to the waveguide-type light-receiving element and the waveguide-type light-receiving element array of the present disclosure, in the element structure in which the ridge waveguide having the light absorption layer and the like is buried by the semiconductor buried layer, the light incident end surface of the first semiconductor buried region is separated from one end of the semiconductor substrate, which improves positioning accuracy of the light incident end surface and allows the window length to be controlled short, thus providing an effect of obtaining the waveguide-type light-receiving element and the waveguide-type light-receiving element array with stable and high photosensitivity.

According to the method for manufacturing the waveguide-type light-receiving element of the present disclosure, in the element structure in which the ridge waveguide having the light absorption layer and the like is buried by the semiconductor buried layer, the light incident end surface of the first semiconductor buried region is formed by etching, which improves the positional accuracy of the light incident end surface formation and allows the window length to be controlled short, thus providing an effect that waveguide-type light-receiving elements with stable and high photosensitivity can be manufactured with high reproducibility.

### BRIEF DESCRIPTION OF THE DRAWINGS

FIG. 1 is a cross-sectional view of a waveguide-type light-receiving element in a direction parallel to a light incident direction according to Embodiment 1.

FIG. 2 is a schematic view of the waveguide-type light-receiving element according to Embodiment 1.

FIG. 3 is a cross-sectional view of the waveguide-type light-receiving element including a ridge waveguide in the direction perpendicular to the light incident direction according to Embodiment 1.

FIG. 4 is a cross-sectional view showing one step of a method for manufacturing a waveguide-type light-receiving element according to Embodiment 1.

FIG. 5 is a cross-sectional view showing one step of the method for manufacturing a waveguide-type light-receiving element according to Embodiment 1.

FIG. 6 is a cross-sectional view showing one step of the method for manufacturing a waveguide-type light-receiving element according to Embodiment 1.

FIG. 7 is a cross-sectional view showing one step of the method for manufacturing a waveguide-type light-receiving element according to Embodiment 1.

FIG. 8 is a cross-sectional view of a waveguide-type light-receiving element in the direction parallel to the light incident direction according to a comparative example.

FIG. 9 is a cross-sectional view of a waveguide-type light-receiving element in the direction parallel to the light incident direction according to Modification 1 of Embodiment 1.

FIG. 10 is a cross-sectional view of a waveguide-type light-receiving element in the direction parallel to the light incident direction according to Modification 2 of Embodiment 1.

FIG. 11 is a cross-sectional view of a waveguide-type light-receiving element in the direction parallel to the light incident direction according to Embodiment 2.

FIG. 12 is a cross-sectional view of a waveguide-type light-receiving element in the direction parallel to the light incident direction according to Embodiment 3.

FIG. 13 is a top view of a waveguide-type light-receiving element array according to Embodiment 4.

FIG. 14 is a top view of a waveguide-type light-receiving element array according to Embodiment 5.

FIG. 15 is a top view of a waveguide-type light-receiving element array according to Embodiment 6.

FIG. 16 is a top view of a waveguide-type light-receiving element array according to Embodiment 7.

FIG. 17 is a top view of a waveguide-type light-receiving element array according to Embodiment 8.

FIG. 18 is a top view of a waveguide-type light-receiving element array according to Embodiment 9.

### DESCRIPTION OF EMBODIMENTS

### Detailed Description of the Invention

### Embodiment 1

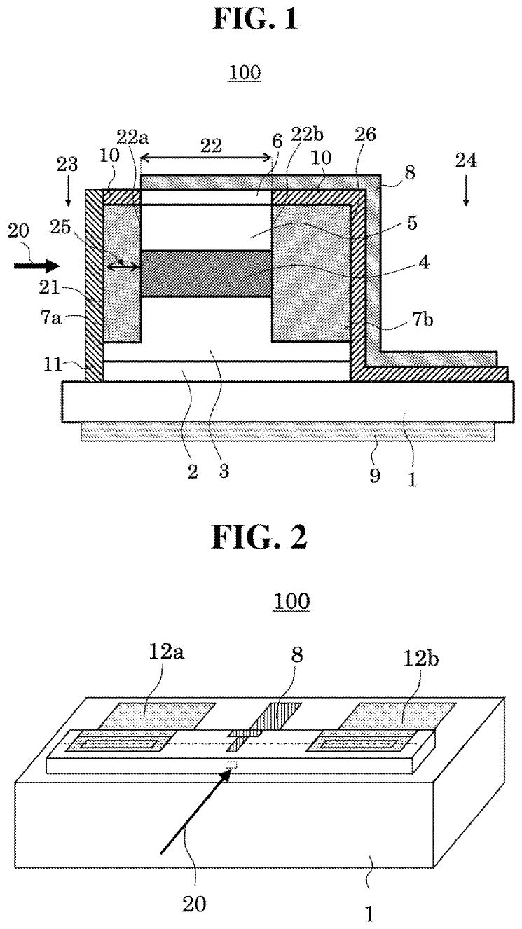

FIG. 1 is a cross-sectional view of a waveguide-type light-receiving element 100 in a direction parallel to a light incident direction according to Embodiment 1. In FIG. 1, the waveguide-type light-receiving element 100 receives an incident light 20 indicated by an arrow.

The waveguide-type light-receiving element 100 includes: a ridge waveguide 22 including at least an n-type contact layer 2 (a first-conductivity-type contact layer), an n-type cladding layer 3 (a first-conductivity-type cladding layer), a light absorption layer 4 made of InGaAs, a p-type cladding layer 5 (a second-conductivity-type cladding layer), and a p-type contact layer 6 (a second-conductivity-type contact layer), which are laminated on a semiconductor substrate 1 (InP substrate), the ridge waveguide 22 having a light incident surface 22a separated from one end of the semiconductor substrate 1 and a rear surface 22b separated from the other end of the semiconductor substrate 1; a first semiconductor buried region 7a provided in contact with the light incident surface 22a of the ridge waveguide 22 and having a light incident end surface 21 that is one surface of the light incident side and separated from the one end of the semiconductor substrate; a second semiconductor buried region 7b provided in contact with the rear surface 22b of the ridge waveguide 22 and having a rear end surface 26 that is one surface opposite the rear surface 22b and separated from the other end of the semiconductor substrate; a passivation film covering the upper surface of the first semiconductor buried region 7a and the second semiconductor buried region 7b; an anti-reflection film 11 covering the light incident end surface 21 of the first semiconductor buried region 7a; a surface electrode 8 provided on the surface of the p-type contact layer 6 and the passivation film 10, and a back surface metal 9 provided on the back side of the semiconductor substrate 1 (InP substrate).

In the above configuration, the first semiconductor buried region 7a and the second semiconductor buried region 7b are collectively referred to as a buried layer 7. The first semiconductor buried region 7a refers to a region of the semiconductor buried layer 7 that is in contact with the light incident surface 22a of the ridge waveguides 22. The second semiconductor buried region 7b refers to a region of the semiconductor buried layer 7 that is in contact with the rear surface 22b of the ridge waveguide 22. The first semiconductor buried region 7a and the second semiconductor buried region 7b each form a part of the buried layer 7, and form one layer as a whole together with portions of the buried layer 7 buried in both side surfaces along the ridge waveguides 22. The InP substrate is one specific example of the semiconductor substrate 1.

A part of the semiconductor buried layer 7 is removed by etching until etching reaches at least the semiconductor substrate 1 (InP substrate) to form a first etching portion 23 and a second etching portion 24. The light incident side surface of the first semiconductor embedded region 7a, which is provided in contact with the light incident surface 22a of the ridge waveguide 22 through which light enters with respect to the ridge waveguide 22, that is, one face of the first etched portion 23 forms the light incident end surface 21. That is, the light incident end surface 21 is one surface on the light incident side of the first semiconductor buried region 7a. The light incident end surface 21 is located at a position separated from the one end of the semiconductor element 1. One surface of the second semiconductor buried region 7b provided in contact with the rear surface 22b of the ridge waveguide 22, that is, one surface of the second etching portion 24 forms the rear end surface 26. That is, the rear end surface 26 is one surface of the second semiconductor buried region 7b. The rear end surface 26 is located at a position separated from the other end of the semiconductor substrate 1.

A portion other than the p-type contact layer 6 on the surface side and a side surface of the first etching portion 23 other than the light incident end surface 21 of the first semiconductor buried region 7a are covered with the passivation film 10. The surface electrode 8 (p-type electrode) is provided on the surface of the p-type contact layer 6. The surface electrode 8 is electrically connected to the p-type contact layer 6. The back surface metal 9 is provided on a part or the entire back surface of the semiconductor substrate 1 (InP substrate).

At least a portion of the light incident end surface 21 of the first semiconductor-buried region 7a through which light enters is covered with the anti-reflection film 11. The window length 25 is a distance from the light incident end surface 21 of the first semiconductor buried region 7a to the light incident surface 22a of the ridge waveguide 22. That is, the window length 25 means the layer thickness of the first semiconductor buried region 7a with respect to the light incident direction.

The rear end surface 26 of the second semiconductor buried region 7b is covered with the passivation film 10 and the surface electrode 8 (p-type electrode). The passivation film 10 and the surface electrode 8 function to reflect light transmitted through the ridge waveguide 22 that cannot be fully absorbed by the light absorbing layer 4 of the ridge waveguide 22 back into the ridge waveguide 22. This is because the reflected light returning into the ridge waveguide 22 contributes to improving photosensitivity of the waveguide-type light-receiving element 100 according to Embodiment 1.

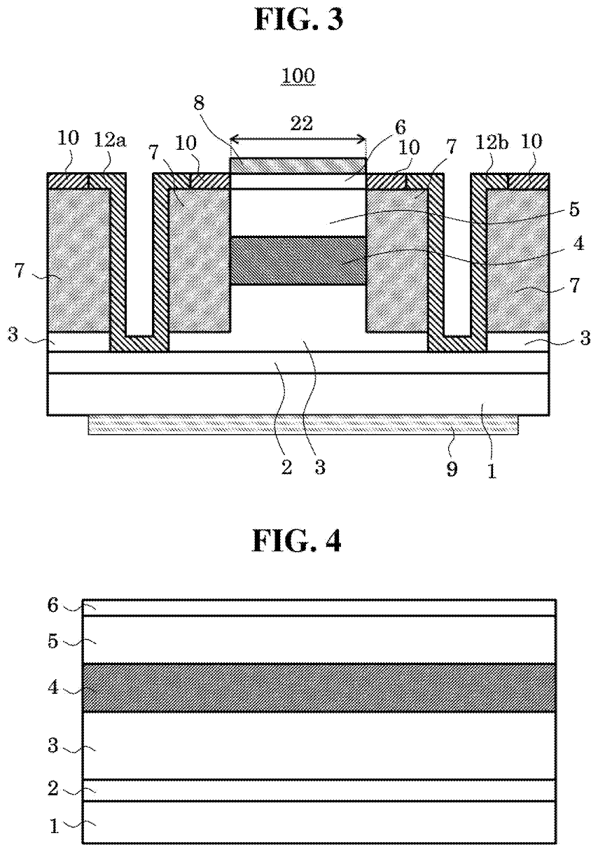

FIG. 2 is a schematic view of the waveguide-type light-receiving element 100 according to Embodiment 1. FIG. 3 is a cross-sectional view of the waveguide-type light-receiving element 100 in the direction perpendicular to the light incident direction according to Embodiment 1. N-type electrodes 12a and 12b electrically connected to the n-type contact layer 2 are provided in portions other than the ridge waveguide 22.

Hereinafter, a method for manufacturing the waveguide-type light-receiving element 100 according to Embodiment 1 will be described.

A liquid phase epitaxy (LPE), a vapor phase epitaxy (VPE), especially a metal organic VPE (MO-VPE), a molecular beam epitaxy (MBE), or the like is used as a crystal growth method for each semiconductor layer constituting the waveguide-type light-receiving element 100 according to Embodiment 1.

The n-type contact layer 2, the n-type cladding layer 3, the light absorption layer 4 made of InGaAs, the p-type cladding layer 5, and the p-type contact layer 6 are sequentially crystal-grown on the semiconductor substrate 1 (InP substrate) by any one of the above-described crystal growth methods. FIG. 4 is a cross-sectional view of each layer after crystal growth.

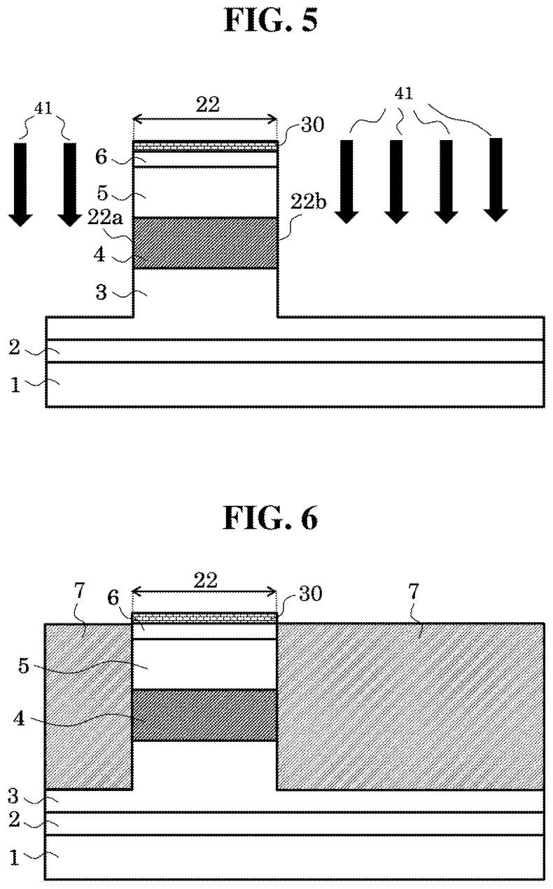

After each semiconductor layer is crystal-grown, an insulating film is formed on a surface of a wafer, and an insulating film mask 30 is formed by a known lithography technique. Using the insulating film mask 30 as an etching mask, dry etching 41 such as reactive ion etching (RIE) is performed to etch portions of the semiconductor layers that are not covered with the insulating film mask 30 to the middle of the n-type cladding layer 3, thereby forming the ridge waveguide 22. Note that wet etching may be used instead of dry etching. FIG. 5 is a cross-sectional view of the ridge waveguide 22 formed by dry etching 41 parallel to the light incident direction.

When the ridge waveguide 22 is formed by dry etching 41, the light incident surface 22a of the ridge waveguide 22 and the rear surface 22b on the side opposite to the light incident surface 22a are formed. That is, both the light incident surface 22a and the rear surface 22b are formed of etched surfaces. The light incident surface 22a of the ridge waveguide 22 is located away from the one end of the semiconductor substrate 1. The rear surface 22b of the ridge waveguide 22 is located away from the other end of the semiconductor substrate 1.

After the ridge waveguide 22 is formed, the semiconductor buried layer 7 is crystal-grown on the etched portion by a crystal growth method such as MO-VPE. At this time, the insulating film mask 30 also functions as a selective crystal growth mask. After the crystal growth of the semiconductor buried layer 7, the insulating film mask 30 is removed by dry etching or wet etching. FIG. 6 is a cross-sectional view of the ridge waveguide 22 parallel to the light incident direction after the crystal growth of the semiconductor buried layer 7.

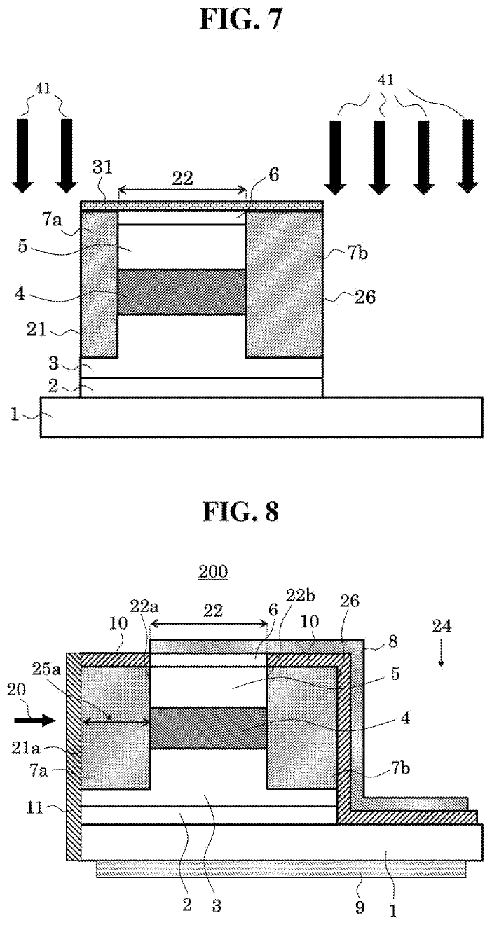

After the crystal growth of the semiconductor buried layer 7, an insulating film is formed on the surface of the wafer, and then an insulating film mask 31 is patterned by a known lithography technique so as to cover the ridge waveguide 22. Thereafter, each semiconductor layer in the area not covered with the insulating film mask 31 is etched by dry etching such as RIE until at least the semiconductor substrate 1 (InP substrate) is reached, thereby forming the first etched portion 23 and the second etched portion 24. The first etching portion 23 and the second etching portion 24 may be formed in the same step, or may be formed in different steps. FIG. 7 is a cross-sectional view of the ridge waveguide 22 parallel to the light incident direction after dry etching.

When the first etching portion 23 and the second etching portion 24 are formed by dry etching, the first semiconductor buried region 7a is provided in contact with the light incident surface 22a of the ridge waveguide 22 and one surface thereof on the light incident side forms the light incident end surface 21, and the second semiconductor buried region 7b is provided in contact with the rear surface 22b of the ridge waveguide 22 and one surface thereof opposite the rear surface 22b forms the rear end surface 26. That is, both the light incident end surface 21 and the rear end surface 26 are formed of etched surfaces. The light incident end surface 21 of the first semiconductor buried region 7a is located at a position away from the one end of the semiconductor substrate 1. The rear end surface 26 of the second semiconductor buried region 7b is located away from the other end of the semiconductor substrate 1.

The passivation film 10 covering the portion other than the p-type contact layer 6 and the side surface of the first etching portion 23 other than the light incident end surface 21 is formed by a method such as plasma-enhanced chemical vapor deposition (PE-CVD) or sputtering. After an insulating film for the passivation film 10 is formed, an unnecessary portion of the insulating film is etched using a known lithography technique while leaving an etching mask only in a desired portion, thereby forming the passivation film 10.

Then, a part of the crystal-grown portion of the semiconductor buried layer 7, that is, a portion immediately above the n-type contact layer 2 is etched by dry etching such as RIE or wet etching.

The surface electrode 8 (p-type electrode) and the n-type electrodes 12a and 12b are formed by depositing a film of a material such as Ti, Pt, or Au by a method such as electron-beam evaporation or sputtering in a state where a mask is opened only at a desired portion using a known lithography technique, and removing the metal at an unnecessary portion. The surface electrode 8 (p-type electrode) and the n-type electrodes 12a and 12b can also be formed by depositing a metal film on the entire surface and then wet etching an unnecessary portion of the metal using a known lithography technique while leaving a mask only on a desired portion.

The back surface metal 9 is formed, on the back surface of the semiconductor substrate 1 (InP substrate), by depositing a metal material such as Ti, Pt, or Au by electron beam evaporation or sputtering with a mask opening only in a desired portion using a known lithography technique, and removing the metal in the unnecessary area. Alternatively, the back surface metal 9 may be formed by depositing a metal film on the entire back surface of the semiconductor substrate 1 (InP substrate) and removing an unnecessary portion of the metal film by wet etching using a known lithography technique while leaving the mask only on the desired portion.

The anti-reflection film 11 is formed on the light incident end surface 21 of the first semiconductor buried region 7a by vapor deposition or sputtering in a state where the wafer subjected to the above-described process is cleaved into chips.

Note that the semiconductor substrate 1 (InP substrate) is preferably a semi-insulating substrate doped with Fe or the like. The n-type contact layer 2 may be made of InGaAs, InP, InGaAsP, AlInAs, AlGaInAs, or a combination thereof.

The n-type cladding layer 3 may be made of InP, InGaAsP, AlInAs, AlGaInAs, or a combination thereof.

The light absorption layer 4 may be made of InGaAsP, InGaAsSb, or a combination thereof instead of InGaAs as long as it is a semiconductor material that generates carriers when light is incident, that is, a semiconductor material having a small bandgap with respect to the incident light 20.

The p-type cladding layer 5 may be made of InP, InGaAsP, AlInAs, AlGaInAs, or a combination thereof.

The p-type contact layer 6 may be made of InGaAs, InP, InGaAsP, AlInAs, AlGaInAs, or a combination thereof.

The semiconductor buried layer 7 may be made of InP, InGaAsP, or the like, and may be doped with Fe or Ru.

In order to relax band discontinuity, a band discontinuity relaxation layer made of InGaAsP, AlGaInAs, or the like may be included between the epitaxial crystal growth layers or between the surface electrode 8 (p-type electrode) and the epitaxial crystal growth layers.

The passivation film 10 may be made of SiO₂, SiN, SiON, or a combination thereof.

Any material may be used for each of the above layers as long as the element characteristics required for the operation of the waveguide-type light-receiving element 100 are obtained. That is, the constituent materials of the waveguide-type light-receiving element 100 are not limited to the specific examples described above.

Group II atoms such as Be, Mg, Zn, and Cd are used as p-type dopants that impart conductivity to a group III-V semiconductor crystal. Similarly, group VI atoms such as S, Se, and Te are used as n-type dopants.

Depending on a semiconductor crystal, group IV atoms such as C, Si, Ge, and Sn are used as amphoteric impurities that function as dopants of either conductivity type. In addition, an atom such as Fe or Ru functions as an insulating dopant which suppresses conductivity and becomes a semi-insulating (SI) type.

The operation of the waveguide-type light-receiving element 100 according to Embodiment 1 will be described in comparison with a waveguide-type light-receiving element 200 of a comparative example shown in FIG. 8. FIG. 8 shows an element structure in which the first etching portion 23 is not formed, as compared with the element structure of the waveguide-type light-receiving element 100 according to Embodiment 1 shown in FIG. 1.

In the method for manufacturing the waveguide-type light-receiving element 200 of the comparative example, the light incident end surface 21a is formed by cleavage or the like after completion of the wafer process. The cleavage step is, for example, a step of forming a scribe line at an end portion of the wafer and applying stress to the scribe line to divide the wafer into chips.

In the cleavage step, there is significant misalignment when physically scribing the scribe line into the wafer and also when cleaving from the scribe line, resulting in variation in the position of the light incident end surface 21a, which is reflected in variation in the window length 25a. The amount of variation in cleavage, that is, the amount of variation in the window length 25a is in the order of several μm to several tens of μm in the case of the comparative example.

When the wafer is cleaved, if the light incident end surface 21a is displaced in a direction away from the light incident surface 22a of the ridge waveguide 22, the window length 25a is formed to be long. On the other hand, in order to prevent the window length 25a from becoming zero even when the light incident end surface 21a is displaced in a direction closer to the light incident surface 22a of the ridge waveguide 22, the design value of the window length 25a needs to be set longer to include a margin in consideration of the variation amount at the time of cleavage. Therefore, in the waveguide-type light-receiving element 200 of the comparative example, the window length 25a tends to be longer than the length necessary for functioning as the window layer.

When the window length 25a is longer than the length required to function as the window layer, light incident on the light incident end surface 21a leaks from the upper portion of the first semiconductor buried region 7a before reaching the light absorption layer 4, resulting in a decrease in the amount of light incident on the light absorption layer 4 and thus a decrease in photosensitivity. The n-type contact layer 2 is located at the bottom of the first semiconductor buried region 7a. When the constituent material of the n-type contact layer 2 is a semiconductor material that absorbs the incident light 20, absorption of light by the n-type contact layer 2 increases as the window length 25a increases, resulting in a decrease in the amount of light incident on the light absorption layer 4 and thus a decrease in photosensitivity. That is, in the waveguide-type light-receiving element 200 of the comparative example, due to the variation of the window length that inevitably occurs in the manufacturing process, the window length 25 becomes unnecessarily long in consideration of the margin for the variation, and as a result, there is a possibility that a problem of causing the decrease in photosensitivity occurs.

On the other hand, in the waveguide-type light-receiving element 100 according to Embodiment 1 shown in FIG. 1, the light incident end surface 21 of the first semiconductor buried region 7a on which the incident light 20 is incident is formed not by cleavage but by an etching step in the manufacturing process. The amount of positional variation in the etching step, that is, the positional accuracy is generally 1 μm or less. Since the light incident surface 22a of the ridge waveguide 22 is formed by etching so as to be separated from the one end of the semiconductor substrate 1, the position of the light incident end surface 21 of the first semiconductor buried region 7a provided in contact with the light incident surface 22a is not affected by the positional variation caused by the cleavage step as in the comparative example. Therefore, by adopting the element structure such as the waveguide-type light-receiving element 100, the positional accuracy of the light incident end surface 21 is significantly improved, so that the design value of the window length 25 can be set to be shorter than that of the comparative example, and as a result, the window length 25 shorter than that of the comparative example can be controlled with high accuracy.

### Effects of Embodiment 1

As described above, according to the waveguide-type light-receiving element 100 and the method for manufacturing the waveguide-type light-receiving element 100 according to Embodiment 1, since the light incident end surface 21 of the first semiconductor buried region 7a is provided to be separated from the one end of the semiconductor substrate 1, the positional accuracy of the light incident end surface 21 of the first semiconductor buried region 7a is improved, so that the window length can be controlled to be short, thus providing an effect that a waveguide-type light-receiving element with stable and high photosensitivity can be obtained, and that such a waveguide-type light-receiving element can be manufactured with high reproducibility.

### Modification 1 of Embodiment 1

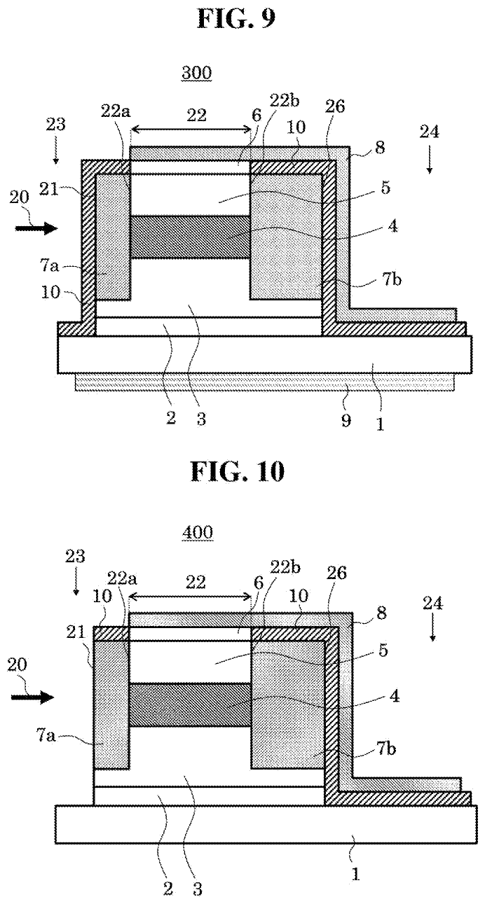

FIG. 9 is a cross-sectional view of a waveguide-type light-receiving element 300 in the direction parallel to the light incident direction according to Modification 1 of Embodiment 1. The element structure is different from that of the waveguide-type light-receiving element 100 according to Embodiment 1 in that a passivation film 10 is formed as an alternative to the anti-reflection film 11 formed on the light incident end surface 21 of the first semiconductor buried region 7a. In other words, the portion of the passivation film 10 covering the light incident end surface 21 of the first semiconductor buried region 7a also functions as an anti-reflection film.

### Effects of Modification 1 of Embodiment 1

As described above, according to the waveguide-type light-receiving element 300 of Modification 1 of Embodiment 1, since the passivation film 10 also functions as the anti-reflection film, the step of forming the anti-reflection film is not required, thus providing an effect of obtaining a waveguide-type light-receiving element which can be manufactured by a simpler manufacturing process.

### Modification 2 of Embodiment 1

FIG. 10 is a cross-sectional view of a waveguide-type light-receiving element 400 in the direction parallel to the light incident direction according to Modification 1 of Embodiment 1. The element structure is different from that of the waveguide-type light-receiving element 100 according to Embodiment 1 in that the back surface metal 9 is not provided. In other words, since the back surface metal is not an essential configuration for the waveguide-type light-receiving element, the back surface metal is omitted.

As shown in FIG. 10, although the waveguide-type light-receiving element 400 operates without an anti-reflection film, it is preferable to provide the anti-reflection film because photosensitivity is improved by providing the anti-reflection film.

### Effects of Modification 2 of Embodiment 1

As described above, according to the waveguide-type light-receiving element 400 of Modification 2 of Embodiment 1, since the element structure in which the back surface metal is not provided is adopted, the step of forming the back surface metal is not required, thus providing an effect of obtaining the waveguide-type light-receiving element that can be manufactured by a simpler manufacturing step.

### Embodiment 2

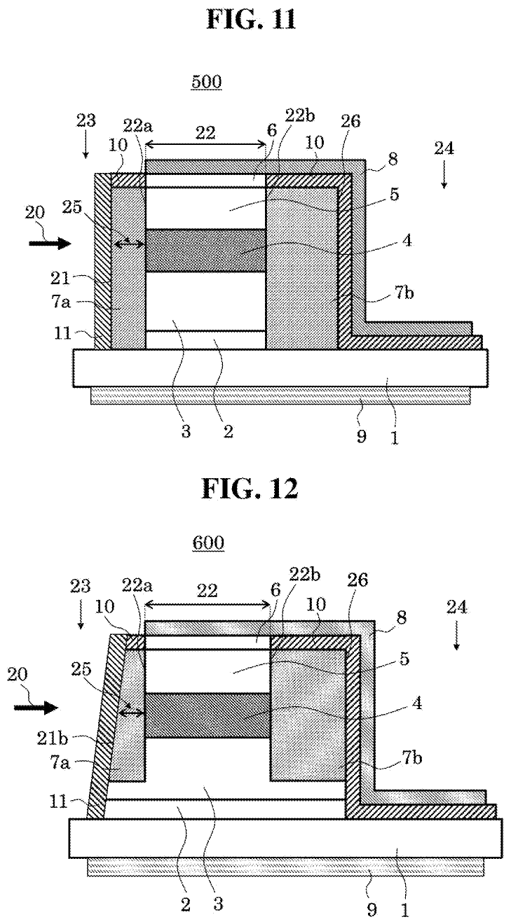

FIG. 11 is a cross-sectional view of a waveguide-type light-receiving element 500 in the direction parallel to the light incident direction according to Embodiment 2. The element structure is different from that of the waveguide-type light-receiving element 100 according to Embodiment 1 in that at least the side surface of the n-type contact layer 2 on the light incident side is also covered with the first semiconductor buried region 7a.

In the waveguide-type light-receiving element 100 according to Embodiment 1, as shown in FIG. 1, the n-type contact layer 2 is located at the bottom of the first semiconductor buried region 7a. When the constituent material of the n-type contact layer 2 is a semiconductor material that absorbs the incident light 20, absorption of light by the n-type contact layer 2 occurs, and as a result, the amount of light incident on the light absorption layer 4 decreases, and thus photosensitivity decreases. Therefore, in the waveguide-type light-receiving element 500 according to Embodiment 2, the n-type contact layer 2 does not exist at the bottom of the first semiconductor buried region 7a, that is, the bottom of the first semiconductor buried region 7a is in contact with the semiconductor substrate 1 by adopting the above-described configuration, so that absorption of light by the n-type contact layer 2 is reduced, and thus photosensitivity of the waveguide-type light-receiving element 500 can be further enhanced.

### Effects of Embodiment 2

As described above, according to waveguide-type light-receiving element 500 according to Embodiment 2, the element structure in which the n-type contact layer 2 does not exist at the bottom of the first semiconductor buried region 7a is adopted, thus providing an effect of obtaining a waveguide-type light-receiving element having even higher photosensitivity.

### Embodiment 3

FIG. 12 is a cross-sectional view of a waveguide-type light-receiving element 600 in the direction parallel to the light incident direction according to Embodiment 3. The element structure is different from that of the waveguide-type light-receiving element 100 according to Embodiment 1 in that the light incident end surface 21b of the first semiconductor buried region 7a is not vertical but inclined when viewed from the cross-sectional direction. That is, the light incident end surface 21b of the first semiconductor buried region 7a is inclined with respect to the surface of the semiconductor substrate 1.

When the incident light 20 enters the waveguide-type light-receiving element 600, the incident light 20 is refracted by the light incident end surface 21b formed obliquely with respect to the incident direction, and thus the light component reflected by the light incident end surface 21b is reduced. That is, the reflected return light can be reduced. As a result, the component of the incident light 20 that enters the waveguide-type light-receiving element 600 increases, so that photosensitivity of the waveguide-type light-receiving element 600 can be enhanced.

### Effects of Embodiment 3

As described above, according to the waveguide-type light-receiving element 600 according to Embodiment 3, since the element structure in which the light incident end surface 21b of the first semiconductor buried region 7a is inclined with respect to the surface of the semiconductor substrate 1 is adopted, the amount of reflected return light can be reduced, thus providing an effect of obtaining a waveguide-type light-receiving element having even higher photosensitivity.

### Embodiment 4

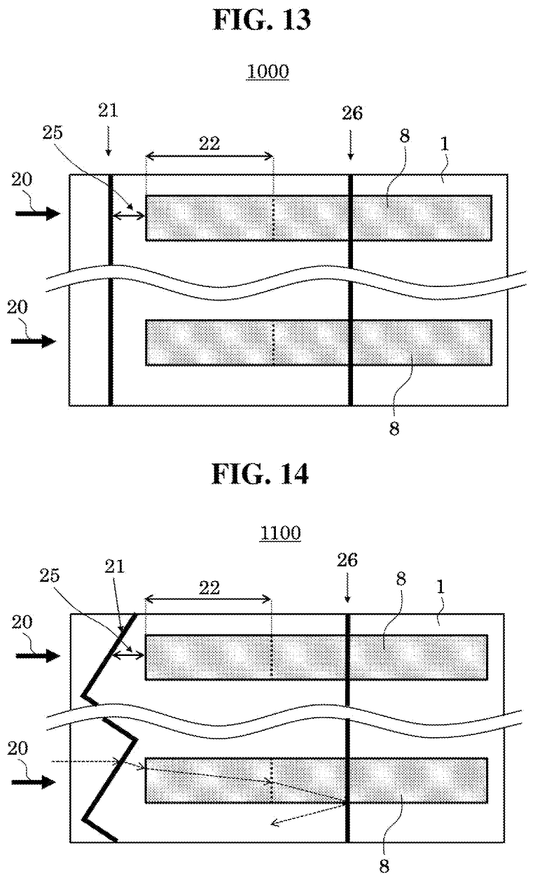

FIG. 13 is a top view of the waveguide-type light-receiving element array 1000 according to Embodiment 4. A plurality of the waveguide-type light-receiving elements 100 according to Embodiment 1 are integrated in parallel such that the ridge waveguides 22 are positioned parallel to each other. In the top views of FIG. 13 and subsequent figures, the passivation film 10 and the anti-reflection film 11 are omitted.

In the waveguide-type light-receiving element array 1000 according to Embodiment 4, the light incident end surfaces 21 of the first semiconductor buried regions 7a are provided in a direction perpendicular to the incident light 20 in a plan view from the surface side of the semiconductor substrate 1.

When a plurality of waveguide-type light-receiving elements 200 of the comparative example shown in FIG. 8 are integrated, variation in cleavage position occurs between each of the waveguide-type light-receiving elements 200 due to angular misalignment of the crystal orientation and pattern, and thus variation in photosensitivity due to variation in the window length inevitably occurs among the integrated waveguide-type light-receiving elements 200.

On the other hand, in the case of the waveguide-type light-receiving element array 1000 according to Embodiment 4, misalignment of the cleavage among the integrated waveguide-type light-receiving elements is reduced, and thus, variation in the window length among the waveguide-type light-receiving elements is also reduced. Therefore, high photosensitivity can be obtained uniformly among the waveguide-type light-receiving elements.

Each of the waveguide-type light-receiving elements constituting the waveguide-type light-receiving element array 1000 according to Embodiment 4 is provided in a direction in which the light incident end surface 21 of the first semiconductor buried region 7a is perpendicular to the incident light 20 in a plan view from the surface side of the semiconductor substrate 1.

### Effects of Embodiment 4

As described above, according to the waveguide-type light-receiving element array 1000 of Embodiment 4, since the plurality of the waveguide-type light-receiving elements 100 according to Embodiment 1 are integrated in parallel such that the ridge waveguides 22 are positioned in parallel to each other, thus providing an effect that high photosensitivity can be obtained uniformly among the waveguide-type light-receiving elements.

### Embodiment 5

FIG. 14 is a top view of a waveguide-type light-receiving element array 1100 according to Embodiment 5. A plurality of the waveguide-type light-receiving elements 100 according to Embodiment 1 are integrated in parallel such that the ridge waveguides 22 are positioned in parallel to each other, but the following points are different from the configuration of Embodiment 4.

That is, the individual integrated waveguide-type light-receiving elements are provided in a direction where the light incident end surface 21 of the first semiconductor buried region 7a is inclined with respect to the incident light 20 in a plan view from the surface side of the semiconductor substrate 1. The light incident end surface 21 of each waveguide-type light-receiving element is inclined at the same angle in the same direction.

In the waveguide-type light-receiving element, to reduce the reflected return light from the light incident end surface 21 of the first semiconductor buried region 7a, a method of changing an angle at which the incident light 20 is reflected is effective by disposing the chip itself so as to be inclined with respect to the light incident direction when viewed from the upper surface side of the chip and positioning the light incident end surface 21 obliquely with respect to the incident light.

However, when such a configuration is simply applied such that the plurality of waveguide-type light-receiving elements are individually integrated, since the optical path length varies among the waveguide-type light-receiving elements, in the case of, for example, a condensing optical system, the spot size of the incident light varies among the waveguide-type light-receiving elements, which causes variation in photosensitivity. On the other hand, by adopting the configuration as in Embodiment 5, the optical path length can be uniformly aligned for each integrated waveguide-type light-receiving element, and the reflected return light can also be reduced.

### Effects of Embodiment 5

As described above, according to the waveguide-type light-receiving element array 1100 of Embodiment 5, since the individual integrated waveguide-type light-receiving elements are provided in a direction where the light incident end surface 21 of the first semiconductor buried region 7a is inclined at the same angle with respect to the incident light 20 in a plan view from the surface side of the semiconductor substrate 1, the reflected return light can be reduced, thus providing an effect that high photosensitivity can be obtained uniformly among the waveguide-type light-receiving elements.

### Embodiment 6

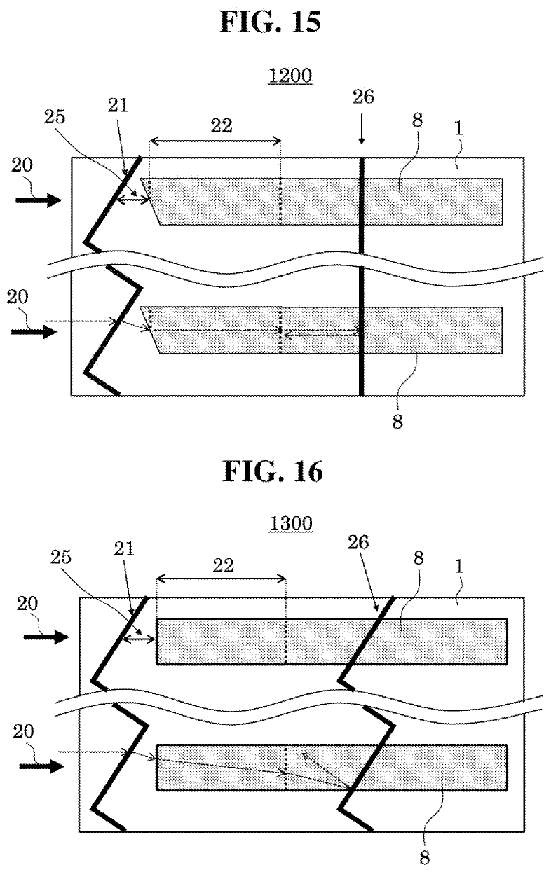

FIG. 15 is a top view of a waveguide-type light-receiving element array 1200 according to Embodiment 6. The configuration of the waveguide-type light-receiving element array 1200 according to Embodiment 6 is different from the configuration according to Embodiment 5 in the following points.

That is, in a plan view from the surface side of the semiconductor substrate 1, the individual integrated waveguide-type light-receiving elements are provided in a direction where the light incident surface 22a of the ridge waveguide 22 is inclined with respect to the incident light 20 toward the side opposite to the light incident end surface 21 of the first semiconductor buried region 7a. Each light incident end surface 21 of each waveguide-type light-receiving element is inclined at the same angle in the same direction, and each light incident surface 22a is also inclined at the same angle in the same direction.

In the configuration according to Embodiment 5, light reaching the ridge waveguide 22 is oblique to the ridge waveguide 22, and is also oblique to light transmitted through the ridge waveguide 22. In this case, light transmitted through the ridge waveguide 22 reaches the rear end surface 26 of the second semiconductor buried region 7b at a certain angle, so that light is not reflected in the direction of returning to the ridge waveguide 22. Therefore, light does not return to the ridge waveguide 22, and thus photosensitivity cannot be increased.

On the other hand, in the configuration according to Embodiment 6, when viewed from the upper surface side, the light incident surface 22a of the ridge waveguide 22 is inclined such that light transmitted through the ridge waveguide 22 is parallel to the light incident direction, whereby light emitted from the rear surface 22b of the ridge waveguide 22 is directed to the rear end surface 26 of the second semiconductor buried region 7b and is reflected by the rear end surface 26 to return to the ridge waveguide 22, resulting in an increase in photosensitivity.

### Effects of Embodiment 6

As described above, in the waveguide-type light-receiving element array 1200 according to Embodiment 6, since the light incident surface 22a of the ridge waveguide 22 is inclined with respect to the incident light 20 toward the side opposite to the light incident end surface 21 of the first semiconductor buried regions 7a in a plan view from the surface side of the semiconductor substrate 1, the reflected return light can be further reduced, thus providing an effect that high photosensitivity can be obtained uniformly among the waveguide-type light-receiving elements.

### Embodiment 7

FIG. 16 is a top view of a waveguide-type light-receiving element array 1300 according to Embodiment 7. The configuration of the waveguide-type light-receiving element array 1200 according to Embodiment 7 is different from the configuration according to Embodiment 5 in the following points.

That is, the individual integrated waveguide-type light-receiving elements are provided in a direction where the rear end surface 26 of the second semiconductor buried region 7b is parallel to the light incident end surface 21 of the first semiconductor buried region 7a in a plan view from the surface side of the semiconductor substrate 1. That is, the rear end surface 26 of the second semiconductor buried region 7b is also inclined in the same direction and at the same angle as the light incident end surface 21 of the first semiconductor buried region 7a. Each light incident end surface 21 of each waveguide-type light-receiving element is inclined at the same angle in the same direction, and each rear end surface 26 is also inclined at the same angle in the same direction.

The angle at which the rear end surface 26 of the second semiconductor buried region 7b is inclined is an angle that is substantially parallel to the light incident end surface 21 of the first semiconductor buried region 7a. In the configuration according to Embodiment 5, light reaching the ridge waveguide 22 is in an oblique direction with respect to the ridge waveguide 22, and light transmitted through the ridge waveguide 22 is also in the oblique direction. In this case, light transmitted through the ridge waveguide 22 reaches the rear end surface 26 of the second semiconductor buried region 7b at a certain angle, so that light is not reflected in the direction of the ridge waveguide 22. Therefore, light does not return to the ridge waveguide 22, and thus photosensitivity cannot be increased. On the other hand, in the configuration according to Embodiment 7, light reaching the rear end surface 26 of the second semiconductor buried region 7b is reflected again in the direction of the ridge waveguide 22, and as a result, photosensitivity can be increased.

### Effects of Embodiment 7

As described above, according to the waveguide-type light-receiving element array 1300 of Embodiment 7, since the rear end surface 26 of the second semiconductor buried region 7b is inclined in the same direction as the light incident end surface 21 of the first semiconductor buried region 7a, the reflected return light can be further reduced, thus providing an effect that high photosensitivity can be obtained uniformly among the waveguide-type light-receiving elements.

### Embodiment 8

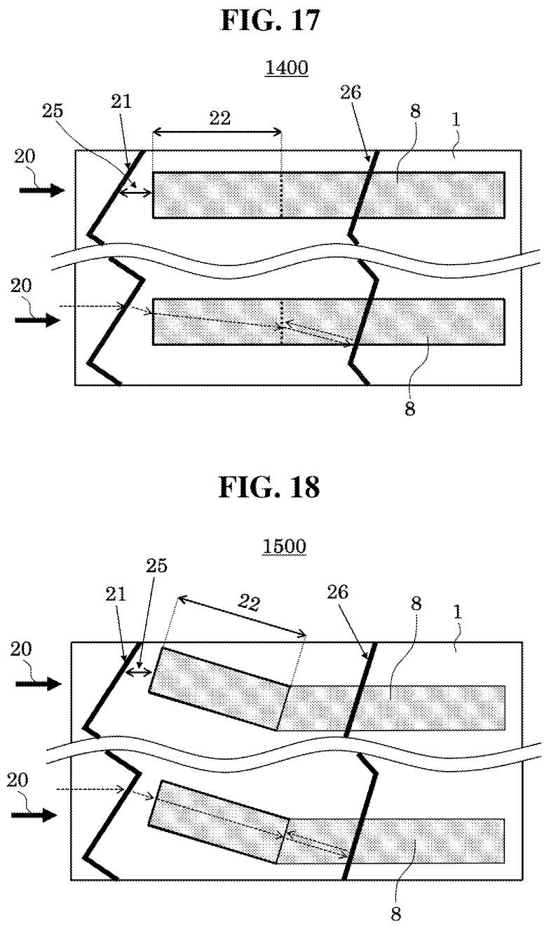

FIG. 17 is a top view of a waveguide-type light-receiving element array 1400 according to Embodiment 8. The configuration of the waveguide-type light-receiving element array 1300 according to Embodiment 8 is different from the configuration according to Embodiment 7 in the following points.

That is, in the individual integrated waveguide-type light-receiving elements, in a plan view from the surface side of the semiconductor substrate 1, the light incident end surface 21 of the first semiconductor buried region 7a is provided in a direction inclined toward the incident light 20, and the rear end surface 26 of the second semiconductor buried region 7b is provided in a different inclined direction from the light incident end surface 21 of the first semiconductor buried region 7a. Each light incident end surface 21 of each waveguide-type light-receiving element is inclined at the same angle in the same direction, and each rear end surface 26 is also inclined at the same angle in the same direction.

The configuration according to Embodiment 8 is changed from the configuration according to Embodiment 7 such that the inclination angle of the rear end surface 26 of the second semiconductor buried region 7b is different from the inclination angle of the light incident end surface 21 of the first semiconductor buried region 7a. Even in the configuration according to Embodiment 7, light reaching the rear end surface 26 of the second semiconductor buried region 7b returns to the ridge waveguide 22. However, when the light incident end surface 21 and the rear end surface 26 are formed in parallel to each other, light transmitted through the ridge waveguide 22 and the rear end surface 26 of the second semiconductor buried region 7b are not opposed to each other, so that some light does not return to the ridge waveguide 22 and thus leaks. Therefore, in the configuration according to Embodiment 8, the inclination angle of the rear end surface 26 is adjusted so as to face light reaching the rear end surface 26 of the second semiconductor buried region 7b, whereby light returning to the ridge waveguides 22 increases, and as a result, photosensitivity can be increased.

### Effects of Embodiment 8

As described above, in the waveguide-type light-receiving element array 1400 according to Embodiment 8, since the inclination angle of the rear end surface 26 of the second semiconductor buried region 7b is changed to be different from the inclination angle of the light incident end surface 21 of the first semiconductor buried region 7a in a plan view from the surface side of the semiconductor substrate 1, the reflected return light can be further reduced, thus providing an effect that high photosensitivity can be obtained uniformly among the waveguide-type light-receiving elements.

### Embodiment 9

FIG. 18 is a top view of a waveguide-type light-receiving element array 1500 according to Embodiment 9. The configuration of the waveguide-type light-receiving element array 1500 according to Embodiment 8 is different from the configuration according to Embodiment 8 in the following points.

That is, the individual integrated waveguide-type light-receiving elements are provided in a direction inclined at an angle at which the ridge waveguide 22 faces the incident light 20 to the ridge waveguide 22 in a plan view from the surface side of the semiconductor substrate 1. The ridge waveguide 22 in each waveguide-type light-receiving elements is each inclined at the same angle in the same direction.

The configuration according to Embodiment 9 is changed from the configuration according to Embodiment 8 such that the ridge waveguide 22 is rotated when viewed from the top side, and the light incident surfaces 22a of the ridge waveguide 22 is positioned so that the ridge waveguide 22 faces light incident on the ridge waveguide 22. In the configuration according to Embodiment 6, light reaching the ridge waveguide 22 is in an oblique direction with respect to the ridge waveguide 22, and light passing through the ridge waveguide 22 is also in an oblique direction. In this case, when the width of the ridge waveguide 22 is narrowed, light may leak from the side surface of the ridge waveguide 22.

On the other hand, by rotating the ridge waveguide 22 itself such that the ridge waveguide 22 faces the incident light 20, as in the configuration according to Embodiment 9, light is incident parallel to the ridge waveguide 22 and is reflected directly opposite at the rear end surface 26 of the second semiconductor buried region 7b, returning to the ridge waveguide 22, thereby increasing photosensitivity.

### Effects of Embodiment 9

As described above, according to the waveguide-type light-receiving element array 1500 of Embodiment 9, in a plan view from the surface side of the semiconductor substrate 1, the ridge waveguide 22 is provided in a direction inclined at an angle facing the incident light 20 to the ridge waveguide 22, so that the reflected return light can be further reduced, thus providing an effect that higher photosensitivity can be obtained uniformly among the waveguide-type light-receiving elements.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 semiconductor substrate (InP substrate)
2 n-type contact layer (first-conductivity-type contact layer)
3 n-type cladding layer (first-conductivity-type cladding layer)
4 light absorption layer
5 p-type cladding layer (second-conductivity-type cladding layer)
6 p-type contact layer (second-conductivity-type
contact layer)
7 semiconductor buried layer
7a first semiconductor buried region
7b second semiconductor buried region
8 surface electrode (p-type electrode)
9 back surface metal
10 passivation film
11 anti-reflection film
12a, 12b n-type electrode
20 incident light
21, 21a, 21b light incident end surface
22 ridge waveguide
22a light incident surface
22b rear surface
23 first etching portion
24 second etching portion
25, 25a window length
26 rear end surface
30, 31 insulating film mask
41 dry etching
100, 200, 300, 400, 500, 600 waveguide-type light-receiving element
1000, 1100, 1200, 1300, 1400, 1500 waveguide-type light-receiving element array

1. A waveguide-type light-receiving element comprising:
a semiconductor substrate;
a ridge waveguide including at least a first-conductivity-type contact layer, a first-conductivity-type cladding layer, a light absorption layer, a second-conductivity-type cladding layer, and a second-conductivity-type contact layer, which are laminated above the semiconductor substrate, the ridge waveguide having a light incident surface separated from one end of the semiconductor substrate and a rear surface separated from the other end of the semiconductor substrate;
a first semiconductor buried region provided in contact with the light incident surface of the ridge waveguide and having a light incident end surface that is one surface on a light incident side and is separated from the one end of the semiconductor substrate, the light incident surface being flat; and
a second semiconductor buried region provided in contact with the rear surface of the ridge waveguide and having a rear end surface that is one surface facing the rear surface and is separated from the other end of the semiconductor substrate, wherein
the first semiconductor buried region functions as a window layer where a layer thickness of the first semiconductor buried region in the light incident direction is a window length.

2. The waveguide-type light-receiving element according to claim 1, wherein
the light incident surface and the rear surface of the ridge waveguide are each formed of an etched surface.

3. The waveguide-type light-receiving element according to claim 2, wherein
the light incident end surface of the first semiconductor buried region and the rear end surface of the second semiconductor buried region are each formed of an etched surface.

4. The waveguide-type light-receiving element according to claim 1, wherein
the light incident end surface of the first semiconductor buried region is covered with an anti-reflection film.

5. The waveguide-type light-receiving element according to claim 1, wherein
at least the light incident end surface and the upper surface of the first semiconductor buried region, and the rear end surface and the upper surface of the second semiconductor buried region are covered with a passivation film.

6. The waveguide-type light-receiving element according to claim 5, wherein
a surface electrode is provided at least on a surface of the second-conductivity-type contact layer.

7. The waveguide-type light-receiving element according to claim 1, wherein
a back surface metal is provided on a back surface side of the semiconductor substrate.

8. The waveguide-type light-receiving element according to claim 1, wherein
at least a bottom portion of the first semiconductor buried region is in contact with the semiconductor substrate.

9. The waveguide-type light-receiving element according to claim 1, wherein
the light incident end surface of the first semiconductor buried region is an inclined plane with respect to the surface of the semiconductor substrate.

10. The waveguide-type light-receiving element according to claim 1, wherein
the light incident end surface of the first semiconductor buried region is provided in a direction perpendicular to the incident light in a plan view from the surface side of the semiconductor substrate.

11. The waveguide-type light-receiving element according to claim 1, wherein
the light incident end surface of the first semiconductor buried region is provided in a direction inclined with respect to the incident light in the plan view from the surface side of the semiconductor substrate.

12. The waveguide-type light-receiving element according to claim 11, wherein
the light incident surface of the ridge waveguide is provided in a direction inclined opposite to the light incident end surface of the first semiconductor buried region with respect to the incident light in the plan view from the surface side of the semiconductor substrate.

13. The waveguide-type light-receiving element according to claim 11, wherein
the rear end surface of the second semiconductor buried region is provided in a direction parallel to the light incident end surface of the first semiconductor buried region in the plan view from the surface side of the semiconductor substrate.

14. The waveguide-type light-receiving element according to claim 11, wherein
the rear end surface of the second semiconductor buried region is provided in a direction inclined at a different angle from the light incident end surface of the first semiconductor buried region in the plan view from the surface side of the semiconductor substrate.

15. The waveguide-type light-receiving element according to claim 1, wherein
the ridge waveguide is inclined in a direction facing light incident on the ridge waveguide in the plan view from the surface side of the semiconductor substrate.

16. A waveguide-type light-receiving element array comprising:
a plurality of the waveguide-type light-receiving elements according to claim 10 integrated in parallel such that the ridge waveguides of the waveguide-type light-receiving elements are located parallel to each other.

17. A method for manufacturing a waveguide-type light-receiving element comprising:
laminating sequentially at least a first-conductivity-type contact layer, a first-conductivity-type cladding layer, a light absorption layer, a second-conductivity-type cladding layer, and a second-conductivity-type contact layer above a semiconductor substrate by crystal growth;
forming a ridge waveguide having a light incident surface on a light incident side and a rear surface on a side opposite to the light incident side by etching the light absorption layer, the second-conductivity-type cladding layer, the second-conductivity-type contact layer, and at least a part of the first-conductivity-type cladding layer;
crystal-growing a semiconductor buried layer so as to bury the ridge waveguide; and
forming, by etching the semiconductor buried layer, a first semiconductor buried region whose layer thickness in the light incident direction is a window length, the first semiconductor buried region having a light incident end surface on a light incident surface side of the ridge waveguide, the light incident end surface being flat and separated from one end of the semiconductor substrate, and a second semiconductor buried region having a rear end surface on a rear surface side of the ridge waveguide, the rear end surface being separated from the other end of the semiconductor substrate and facing the rear surface.
